(19) United States
(12) Patent Application Publication
(10) Pub. No.: US 2026/0142618 A1
(43) Pub. Date: May 21, 2026

(54) Oscillator circuit having voltage-withstanding mechanism

(71) Applicant: REALTEK SEMICONDUCTOR CORPORATION, Hsinchu (TW)

(72) Inventor: YUNG-CHUNG CHEN, Hsinchu (TW)

(21) Appl. No.: 19/388,434

(22) Filed: Nov. 13, 2025

(30) Foreign Application Priority Data
Nov. 15, 2024 (TW) 113144151

(51) Int. Cl. H03B 5/12

(52) U.S. Cl. CPC H03B 5/1212; H03B 5/1228; H03B 5/1265; H03B 2200/009

(57) ABSTRACT

An oscillator circuit having voltage-withstanding mechanism is provided. An inductor circuit is coupled to a pair of oscillating output terminals. A cross-coupled transistor circuit is coupled between the oscillating output terminals and a first terminal. A capacitor circuit is coupled between the oscillating output terminals. A first source degeneration circuit includes a first inductor, a first capacitor, a second capacitor and a first source degeneration circuit. The first inductor is coupled between the first terminal and a first power voltage. The first capacitor is coupled between the first terminal and a second terminal. The second capacitor is coupled between the first power voltage and a third terminal that is coupled to a second power voltage. The first source degeneration is coupled between the second terminal and the third terminal and is turned on based on a first feeding voltage.

### BACKGROUND OF THE INVENTION

### 1. Field of the Invention

The present invention relates to an oscillator circuit having a voltage-withstanding mechanism.

### 2. Description of Related Art

Oscillator circuits, especially LC oscillator circuits, are circuits that include a capacitor circuit and an inductor circuit electrically coupled together and operate according to an oscillating activity. Oscillator circuits are widely used in circuits such as, but not limited to oscillators, filters, tuners, and mixers.

Oscillator circuits are often equipped with circuits that lower the phase noise. However, the circuits that lower the phase noise may suffer from a cross voltage that is too large during operation such that the internal components are damaged. If the voltage and the current are lowered to prevent the cross voltage that is too large, the performance of the circuits that lower the phase noise degrades. The requirements to lower the phase noise and increase the voltage-withstanding ability are hard to satisfy at the same time.

### SUMMARY OF THE INVENTION

In consideration of the problem of the prior art, an object of the present invention is to supply an oscillator circuit having a voltage-withstanding mechanism.

The present invention discloses an oscillator circuit having voltage-withstanding mechanism that includes an inductor circuit, a cross-coupled transistor circuit, a capacitor circuit and a first source degeneration circuit. The inductor circuit is electrically coupled to a pair of oscillating output terminals. The cross-coupled transistor circuit is electrically coupled between the oscillating output terminals and a first terminal. The capacitor circuit is electrically coupled between the oscillating output terminals. The first source degeneration circuit includes a first inductor, a first capacitor, a second capacitor and a first source degeneration transistor. The first inductor is electrically coupled between the first terminal and a first power voltage. The first capacitor is electrically coupled between the first terminal and a second terminal. The second capacitor is electrically coupled between the first power voltage and a third terminal, wherein the third terminal is electrically coupled to a second power voltage. The first source degeneration transistor is electrically coupled between the second terminal and the third terminal and controlled to be turned on by a first feeding voltage.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a circuit diagram of an oscillator circuit having a voltage-withstanding mechanism according to an embodiment of the present invention.

FIG. 2 illustrates a circuit diagram of an oscillator circuit 200 having a voltage-withstanding mechanism according to an embodiment of the present invention.

### DETAILED DESCRIPTION OF THE PREFERRED EMBODIMENTS

An aspect of the present invention is to provide an oscillator circuit having a voltage-withstanding mechanism that uses a transistor electrically coupled to a second power voltage in the source degeneration circuit as a switch element and forms a path with a high frequency and a low impedance between a first power voltage and the second power voltage by disposing a bypass capacitor such that a source degeneration circuit can prevent the cross voltage of the switch element from being too large and maintain the efficiency of the phase noise lowering mechanism at the same time.

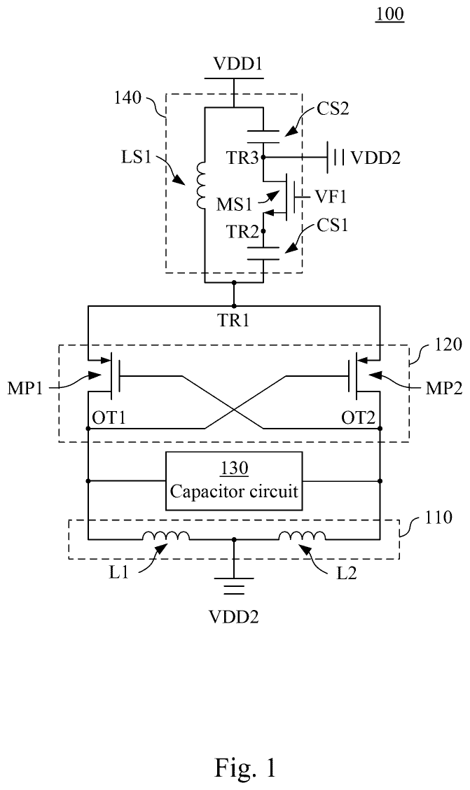

Reference is now made to FIG. 1. FIG. 1 illustrates a circuit diagram of an oscillator circuit 100 having a voltage-withstanding mechanism according to an embodiment of the present invention.

The oscillator circuit 100 operates according to a voltage difference between a first power voltage VDD1 and a second power voltage VDD2 and the second power voltage VDD2, in an embodiment, is a ground level. The oscillator circuit 100 includes an inductor circuit 110, a cross-coupled transistor circuit 120, a capacitor circuit 130 and a first source degeneration circuit 140.

The inductor circuit 110 is electrically coupled to a pair of the oscillating output terminals OT1 and OT2. In the present embodiment, the inductor circuit 110 is electrically coupled between the oscillating output terminals OT1 and OT2 and the second power voltage VDD2. In FIG. 1, the inductor circuit 110 is illustrated to include an inductor L1 electrically coupled between the oscillating output terminal OT1 and the second power voltage VDD2 and an inductor L2 electrically coupled between the oscillating output terminal OT2 and the second power voltage VDD2. In practical implementation, the inductor circuit 110 can be implemented by an inductor coil to be equivalent to the inductor L1 and the inductor L2 in FIG. 1, or by two coils in the form of a twin inductor.

The cross-coupled transistor circuit 120 is electrically coupled between the oscillating output terminals OT1 and OT2 and the first terminal TR1.

The cross-coupled transistor circuit 120 includes a first transistor MP1 and a second transistor MP2. In the present embodiment, each of the first transistor MP1 and the second transistor MP2 is a P-type transistor. However, the present invention is not limited thereto.

The first transistor MP1 has a first drain electrically coupled a first oscillating output terminal (e.g., the oscillating output terminal OT1) of the oscillating output terminals OT1 and OT2 and a first source electrically coupled to a first terminal TR1. The second transistor MP2 has a second drain electrically coupled to second oscillating output terminal (e.g., the oscillating output terminal OT2) of the oscillating output terminals OT1 and OT2 and a second source electrically coupled to the first terminal TR1. A first gate of the first transistor MP1 is electrically coupled to the second oscillating output terminal (e.g., the oscillating output terminal OT2). A second gate of the second transistor MP2 is electrically coupled to first oscillating output terminal (e.g., the oscillating output terminal OT1).

The capacitor circuit 130 is electrically coupled between the oscillating output terminals OT1 and OT2. In FIG. 1, in order to simplify the drawing, the capacitor circuit 130 is illustrated to be a block. However, in an embodiment, the capacitor circuit 130 can be a switch capacitor array or a plurality of voltage-controlled capacitors (not illustrated in the figure), and selective include an output buffer circuit (not illustrated in the figure). In another embodiment, the capacitor circuit 130 includes at least one metal-oxide-metal capacitor (metal-oxide-metal capacitor; MOMCAP).

The first source degeneration circuit 140 includes a first inductor LS1, a first capacitor CS1, a second capacitor CS2 and a first source degeneration transistor MS1.

The first inductor LS1 is electrically coupled between the first terminal TR1 and the first power voltage VDD1. The first capacitor CS1 is electrically coupled between the first terminal TR1 and second terminal TR2. The second capacitor CS2 is electrically coupled between the first power voltage VDD1 and a third terminal TR3. The third terminal TR3 is electrically coupled to the second power voltage VDD2.

The first source degeneration transistor MS1 is electrically coupled between second terminal TR2 and the third terminal TR3, and is controlled to be turned on by a first feeding voltage VF1. In the present embodiment, the first source degeneration transistor MS1 is implemented by a N-type transistor. However, the present invention is not limited thereto.

In the configuration described above, the inductor circuit 110 is a main oscillating inductor used to oscillate with the capacitor circuit 130 such that the inductor circuit 110 and the capacitor circuit 130 together determine the oscillating frequency. The cross-coupled transistor circuit 120 provides a negative resistance required by the oscillating behavior.

The first source degeneration circuit 140 is configured to oscillate to lower the phase noise. In an embodiment, when the oscillating frequency of the inductor circuit 110 is F, the first source degeneration circuit 140 is preferably to have the oscillating frequency of 2F.

In the components included by the first source degeneration circuit 140, the second capacitor CS2 serves as a bypass capacitor to form a path with a high frequency and a low impedance between the first power voltage VDD1 and the grounded third terminal TR3 The first inductor LS1, the first capacitor CS1 and the first source degeneration transistor MS1 thus form a oscillating loop.

When a first capacitance of the first capacitor CS1 is C1 and a second capacitance of the second capacitor CS2 is C2, an equivalent capacitance of the first capacitor CS1 and the second capacitor CS2 coupled in series is (C1×C2)/(C1+C2). In an embodiment, the second capacitance C2 is far larger than the first capacitance C1 such that the equivalent capacitance of the first capacitor CS1 and the second capacitor CS2 is close to the first capacitance. In an embodiment, the term “close” means that the difference between the equivalent capacitance and the first capacitance C1 is smaller than a threshold value and can be considered to equal to each other.

In some approaches, the switch element that initiates the oscillating behavior of the loop that includes the inductor and the capacitor in the source degeneration circuit is easy to be damaged due to the cross voltage that is too large. However, once the power voltage is lowered in order to prevent the cross voltage of the switch element from being too large, the ability of the source degeneration circuit to lower the phase noise degrades.

The oscillator circuit of the present invention uses a transistor electrically coupled to a second power voltage in the source degeneration circuit as a switch element and forms a path with a high frequency and a low impedance between a first power voltage and the second power voltage by disposing a bypass capacitor such that a source degeneration circuit can prevent the cross voltage of the switch element from being too large and maintain the efficiency of the phase noise lowering mechanism at the same time.

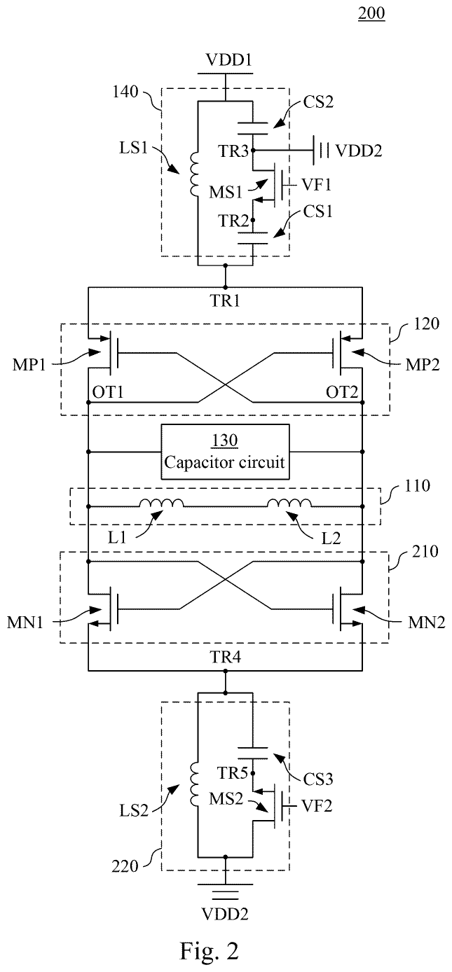

Reference is now made to FIG. 2. FIG. 2 illustrates a circuit diagram of an oscillator circuit 200 having a voltage-withstanding mechanism according to an embodiment of the present invention.

The oscillator circuit 200 also operates according to the voltage difference between the first power voltage VDD1 and the second power voltage VDD2 and also includes the inductor circuit 110, the cross-coupled transistor circuit 120, the capacitor circuit 130 and the first source degeneration circuit 140. The configuration and operation of the components identical to those in FIG. 1 are not described herein.

In the present embodiment, the oscillator circuit 200 further includes a cross-coupled transistor circuit 210 and a second source degeneration circuit 220.

The cross-coupled transistor circuit 210 is electrically coupled between the oscillating output terminals OT1 and OT2 and fourth terminal TR4.

More specifically, in the present embodiment, the cross-coupled transistor circuit 210 includes a first transistor MN1 and a second transistor MN2. In the present embodiment, each of the first transistor MN1 and the second transistor MN2 is an N-type transistor. However, the present invention is not limited thereto.

The first transistor MN1 has a first drain electrically coupled to a first oscillating output terminal (e.g., the oscillating output terminal OT1) of the oscillating output terminals OT1 and OT2 and a first source electrically coupled to a fourth terminal TR4. The second transistor MN2 has a second drain electrically coupled to a second oscillating output terminal (e.g., the oscillating output terminal OT2) of the oscillating output terminals OT1 and OT2 and a second source electrically coupled to the fourth terminal TR4. A first gate of the first transistor MN1 is electrically coupled to the second oscillating output terminal (e.g., the oscillating output terminal OT2) and a second gate of the second transistor MN21 is electrically coupled to the first oscillating output terminal (e.g., the oscillating output terminal OT1).

The cross-coupled transistor circuit 210□ the cross-coupled transistor circuit 120 actually form a pair of complementary metal-oxide-semiconductor (CMOS) transistor configuration.

The second source degeneration circuit 220 is electrically coupled between fourth terminal TR4 and the second power voltage VDD2.

More specifically, in the present embodiment, the second source degeneration circuit 220 includes a second inductor LS2, a third capacitor CS3 and a second source degeneration transistor MS2. The second inductor LS2 is electrically coupled between fourth terminal TR4 and the second power voltage VDD2. The third capacitor CS3 is electrically coupled between fourth terminal TR4 and fifth terminal TR5. The second source degeneration transistor MS2 is electrically coupled between a fifth terminal TR5 and the second power voltage VDD2 and is controlled to be turned on by a second feeding voltage VF2. In the present embodiment, the second source degeneration transistor MS2 is a N-type transistor. However, the present invention is not limited thereto.

The configuration of the second source degeneration circuit 220 is similar to that of the first source degeneration circuit 140. However, since the second power voltage VDD2 is a ground level voltage, the second source degeneration transistor MS2 does not require an additional bypass capacitor to be coupled to the second power voltage VDD2. As a result, similar to the first source degeneration circuit 140, the second source degeneration circuit 220 is able to lower the phase noise when the oscillating behavior begins. The detail is not described herein.

It is appreciated that the embodiments described above are merely an example. In other embodiments, it should be appreciated that many modifications and changes may be made by those of ordinary skill in the art without departing, from the spirit of the disclosure.

In summary, the present invention discloses the oscillator circuit having the voltage-withstanding mechanism that uses a transistor electrically coupled to a second power voltage in the source degeneration circuit as a switch element and forms a path with a high frequency and a low impedance between a first power voltage and the second power voltage by disposing a bypass capacitor such that a source degeneration circuit can prevent the cross voltage of the switch element from being too large and maintain the efficiency of the phase noise lowering mechanism at the same time.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. An oscillator circuit having voltage-withstanding mechanism, comprising:
an inductor circuit electrically coupled to a pair of oscillating output terminals;
a cross-coupled transistor circuit electrically coupled between the oscillating output terminals and a first terminal;
a capacitor circuit electrically coupled between the oscillating output terminals; and
a first source degeneration circuit comprising:
a first inductor electrically coupled between the first terminal and a first power voltage;
a first capacitor electrically coupled between the first terminal and a second terminal;
a second capacitor electrically coupled between the first power voltage and a third terminal, wherein the third terminal is electrically coupled to a second power voltage; and
a first source degeneration transistor electrically coupled between the second terminal and the third terminal and controlled to be turned on by a first feeding voltage.

2. The oscillator circuit of claim 1, wherein the cross-coupled transistor circuit comprises:
a first transistor having a first drain electrically coupled to a first oscillating output terminal of the oscillating output terminals and a first source electrically coupled to the first terminal; and
a second transistor having a second drain electrically coupled to a second oscillating output terminal of the oscillating output terminals and a second source electrically coupled to the first terminal;
wherein a first gate of the first transistor is electrically coupled to the second oscillating output terminal and a second gate of the second transistor is electrically coupled to the first oscillating output terminal.

3. The oscillator circuit of claim 1, wherein the inductor circuit is electrically coupled between the oscillating output terminals and the second power voltage.

4. The oscillator circuit of claim 1, further comprising:
a cross-coupled transistor circuit electrically coupled between the oscillating output terminals and a fourth terminal; and
a second source degeneration circuit electrically coupled between the fourth terminal and the second power voltage.

5. The oscillator circuit of claim 4, wherein the cross-coupled transistor circuit comprises:
a first transistor having a first drain electrically coupled to a first oscillating output terminal of the oscillating output terminals and a first source electrically coupled to the fourth terminal; and
a second transistor having a second drain electrically coupled to a second oscillating output terminal of the oscillating output terminals and a second source electrically coupled to the fourth terminal;
wherein a first gate of the first transistor is electrically coupled to the second oscillating output terminal and a second gate of the second transistor is electrically coupled to the first oscillating output terminal.

6. The oscillator circuit of claim 4, wherein the second source degeneration circuit comprises:
a second inductor electrically coupled between the fourth terminal and the second power voltage;
a third capacitor electrically coupled between the fourth terminal and a fifth terminal; and
a second source degeneration transistor electrically coupled between the fifth terminal and the second power voltage and is controlled to be turned on by a second feeding voltage.

7. The oscillator circuit of claim 1, wherein a first capacitance of the first capacitor is C1, a second capacitance of the second capacitor is C2, and an equivalent capacitance of the first capacitor and the second capacitor coupled in series is (C1×C2)/(C1+C2).

8. The oscillator circuit of claim 7, wherein the second capacitance is larger than the first capacitance such that equivalent capacitance of the first capacitor and the second capacitor is close to the first capacitance.

9. The oscillator circuit of claim 1, wherein the capacitor circuit is a switch capacitor array or a plurality of voltage-controlled capacitors and selectively comprises an output buffer circuit.

10. The oscillator circuit of claim 9, wherein the capacitor circuit comprises at least one metal-oxide-metal capacitor (MOMCAP).
